(19) United States
(12) Patent Application Publication
(10) Pub. No.: US 2025/0157829 A1
(43) Pub. Date: May 15, 2025

(54) SEMICONDUCTOR DEVICE FABRICATION METHOD AND LEAD FRAME WITH SIDE PORTION MOLD LOCKING STRUCTURE

(71) Applicant: Texas Instruments Incorporated, Dallas, TX (US)

(72) Inventors: Mark Zhang, Chengdu (CN); Chloe Zhang, Chengdu (CN); ZuoHui Chen, Chengdu (CN); Lei Tang, Chengdu (CN); Eugene Lee, Cheras (MY); Anis Fauzi Bin Abdul Aziz, Batu Berendam (MY); Von Mark Mendoza, Baguio City (PH)

(21) Appl. No.: 18/506,835

(22) Filed: Nov. 10, 2023

(51) Int. Cl. H01L 21/56; H01L 23/00; H01L 23/495

(52) U.S. Cl. CPC H01L 21/565; H01L 23/49541; H01L 24/92; H01L 2224/92247

(57) ABSTRACT

A method of fabricating an electronic device includes: mounting a semiconductor die in a unit area of a lead frame; electrically connecting the semiconductor die to a conductive feature in the unit area of the lead frame; performing a molding process to form a molded package structure that extends through multiple unit areas of the lead frame along a first column of the lead frame and extends under a mold locking structure in a side portion of the lead frame at an end of the first column to oppose separation of the molded package structure from the side portion of the lead frame; separating the first column from an adjacent second column of the lead frame; separating an electronic device of the unit area from the lead frame; and separating the side portion from the first column of the lead frame.

### BACKGROUND

Packaged electronic devices may include a semiconductor die and a molded package structure with externally accessible leads for interconnecting one or more internal components to a circuit board. Mold bar peeling or separation from a lead frame during fabrication can stress the package and cause cracks in the molded package structure prior to final device separation. Subsequent fabrication processing can worsen cracking and propagate cracks. Package cracking can lead to damage or degradation of the semiconductor die and/or electrical interconnections within the packaged electronic device.

### SUMMARY

In one aspect, a method of fabricating an electronic device includes mounting a semiconductor die in a unit area of a lead frame, electrically connecting the semiconductor die to a conductive feature in the unit area of the lead frame, performing a molding process to form a molded package structure that extends through multiple unit areas of the lead frame along a first column of the lead frame and extends under a mold locking structure in a side portion of the lead frame at an end of the first column to oppose separation of the molded package structure from the side portion of the lead frame, separating the first column from an adjacent second column of the lead frame, separating an electronic device of the unit area from the lead frame, and separating the side portion from the first column of the lead frame.

In another aspect, a lead frame has interior and side portion, the interior portion having unit areas arranged in an array with rows along a first direction and columns along an orthogonal second direction, the respective unit areas having a die attach pad and a conductive feature in a plane of the first and second directions, and the side portion extending from the interior portion to an edge of the lead frame and including a mold locking structure aligned with a column and spaced apart from the interior portion, the mold locking structure extending outside the plane of the first and second directions.

### BRIEF DESCRIPTION OF THE DRAWINGS

FIG. 1 is a top plan view of a lead frame panel array with mold locking structures in a side portion at the ends of columns of unit areas according to one aspect.

FIG. 1A is a partial top plan view showing further details of the side portion mold locking structures in the lead frame panel array of FIG. 1.

FIG. 1B is a partial sectional side elevation view of a mold locking structure taken along line 1B-1B of FIG. 1A.

FIG. 2 is a flow diagram showing a method for making an electronic device according to another aspect.

FIG. 3 is a partial top plan view of a portion of the lead frame panel array undergoing die attach processing according to an implementation of the method of FIG. 2.

FIG. 4 is a partial top plan view of a portion of the lead frame panel array undergoing electrical connection processing according to an implementation of the method of FIG. 2.

FIG. 5 is a partial top plan view of a portion of the lead frame panel array undergoing molding processing according to an implementation of the method of FIG. 2.

FIG. 5A is a partial sectional side elevation view of first and second raised features of the mold locking structure of the lead frame panel array during the molding processing taken along line 5A-5A of FIG. 5.

FIG. 6 is a partial top plan view of a portion of the lead frame panel array undergoing lead trimming processing along the column direction to separate adjacent columns from one another according to an implementation of the method of FIG. 2.

FIG. 7 is a partial top plan view of a portion of the lead frame panel array undergoing row direction package separation processing to separate packaged electronic devices from the array according to an implementation of the method of FIG. 2.

FIG. 8 is a top perspective view of a packaged electronic device fabricated according to an implementation of the method of FIG. 2.

FIG. 8A a is a bottom perspective view of the packaged electronic device of FIG. 8.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about.” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for ease of description in connection with a particular drawing, where such are not to be construed as limiting with respect to the claims. Various disclosed methods and lead frame apparatus of the present disclosure may be beneficially applied to manufacturing an electronic device such as an integrated circuit. While such examples may be expected to provide various improvements, no particular result is a requirement of the present disclosure unless explicitly recited in a particular claim.

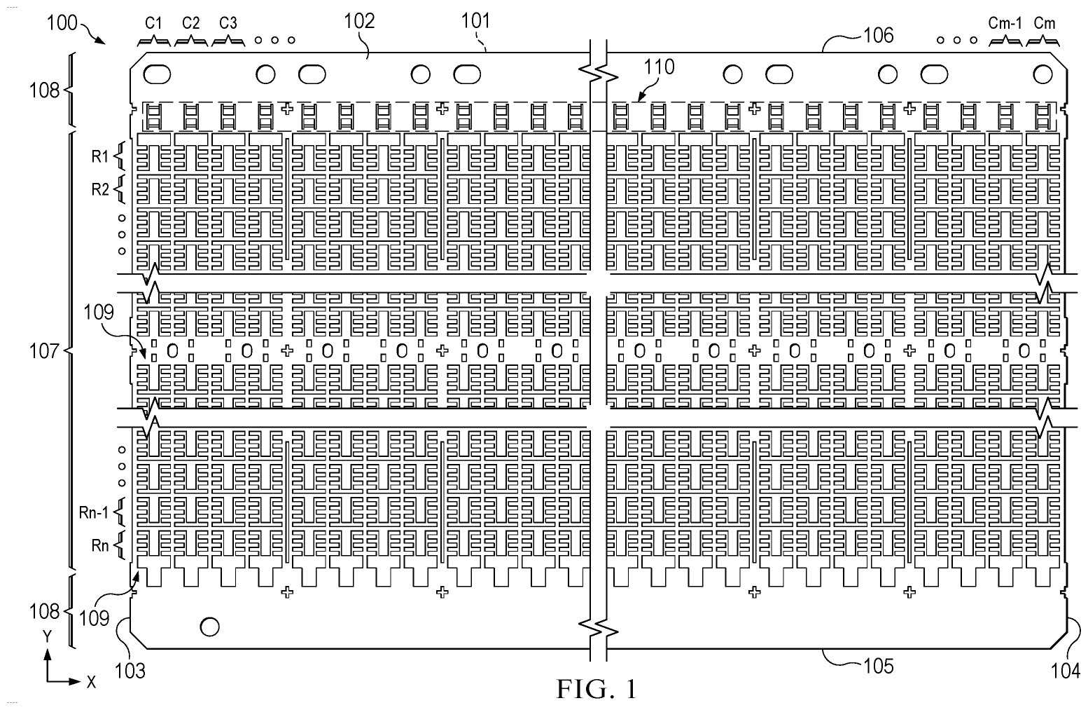

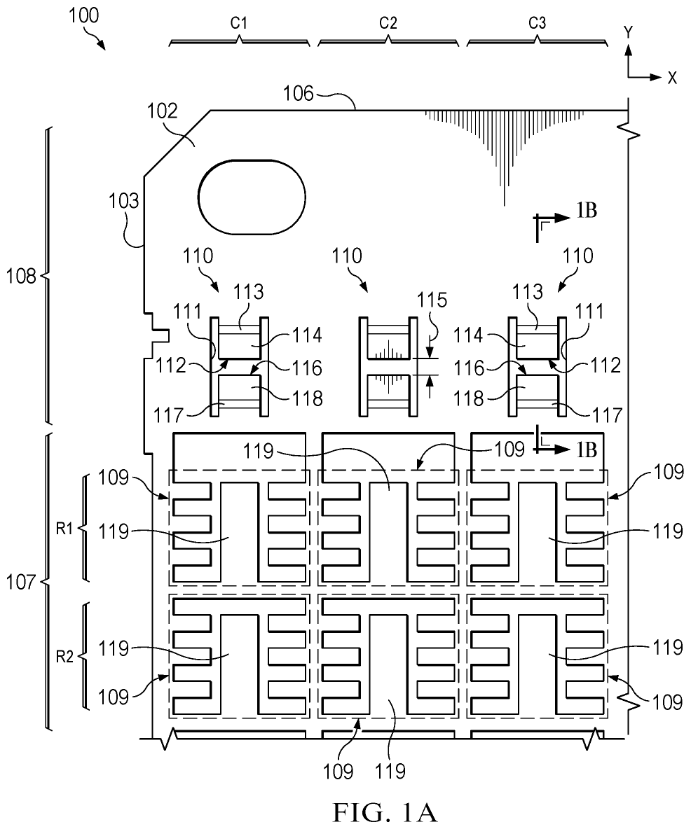

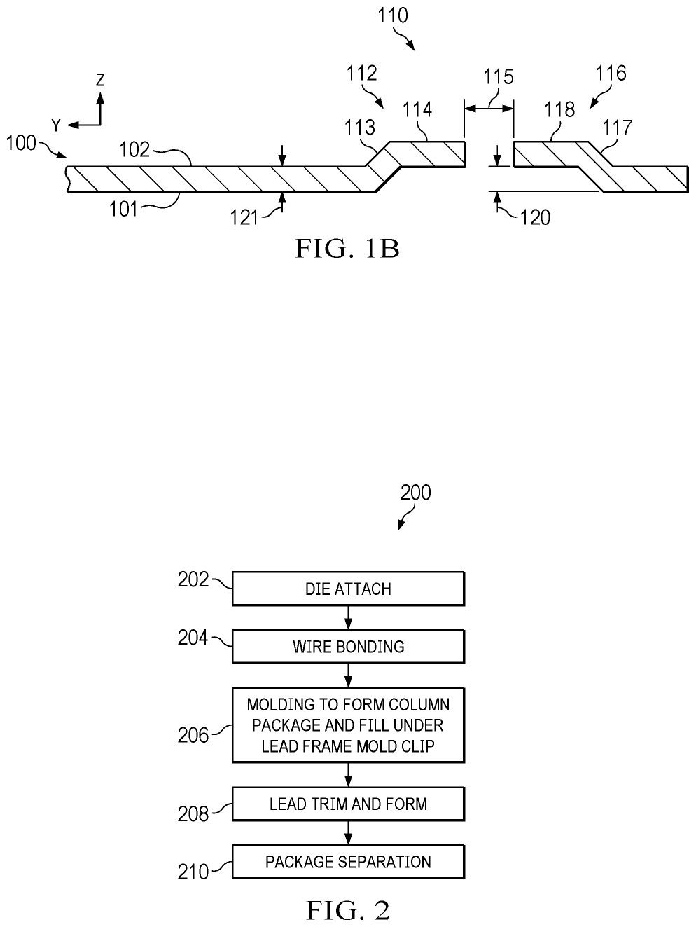

FIGS. 1-1B show a lead frame 100, also referred to as a lead frame panel array, illustrated in an example position in a three-dimensional space with a first direction X (FIGS. 1 and 1A), a perpendicular (orthogonal) second direction Y, and a third direction Z (FIG. 1B) that is perpendicular (orthogonal) to the respective first and second directions X and Y. Structures or features along any two of these directions are orthogonal to one another. As best shown in FIGS. 1 and 1B), the lead frame 100 has opposite first and second (e.g., bottom and top) sides 101 and 102, respectively, which are spaced apart from one another along the third direction Z, as well as opposite third and fourth sides 103 and 104 (FIG. 1) spaced apart from one another along the first direction X, and fifth and sixth sides 105 and 106 that are spaced apart from one another along the second direction Y in the illustrated position.

As best shown in FIGS. 1 and 1A, the lead frame 100 has an interior portion 107 (e.g., also referred to as a first portion) as well as to (e.g., upper and lower) side portions 108 (e.g., also referred to as second portions or instances of a second portion). The interior portion 107 has unit areas 109 (FIGS. 1 and 1A) that are arranged in an array with an integer number n rows R1. R2 . . . . Rn−1, Rn along the first direction X and an integer number m columns C1, C2, C3 . . . . Cm−1, Cm along the second direction Y.

The individual unit areas 109 can include one or more conductive metal features corresponding to prospective conductive leads as well as one or more die attach pad structures suitable for attachment of one or more semiconductor dies within the respective unit areas 109. The side portions 108 each extend along the second direction Y from the interior portion 107 to an edge of the lead frame 100 along a respective one of the fifth and sixth sides 105 and 106. The lead frame 100 extends in a plane of the first and second directions X and Y, respectively (e.g., an X-Y plane) and bottom sides of the prospective lead structures are approximately coplanar with one another to facilitate subsequent soldering of a fabricated packaged electronic device to a host printed circuit board (not shown). The lead frame 100 in one example is a flat structure. In another example, the lead frame 100 includes one or more raised features, such as half etch features, for example, to accommodate die attach pad structures, tie bars, dam bars, etc. having bottom sides that are not coplanar with the bottom sides of the prospective leads.

In the illustrated example, the upper side portion 108 includes a mold locking structure 110 aligned with each respective column and the mold locking structures 110 are spaced apart from the interior portion 107. Each mold locking structure 110 in this example is spaced apart from the highest unit area 109 of the interior portion 107 along the second direction Y. In another example, additional mold locking structures 110 are provided in the lower side portion 108 spaced apart from the lowest unit area 109 of the interior portion 107 and individually aligned with each respective column of the lead frame panel array 100. In another implementation, one or more of the columns have a mold locking structure 110 in only one of the upper and lower side portions 108. In these or another implementation, one of the columns has no aligned mold locking structures 110 in either of the upper and lower side portions 108.

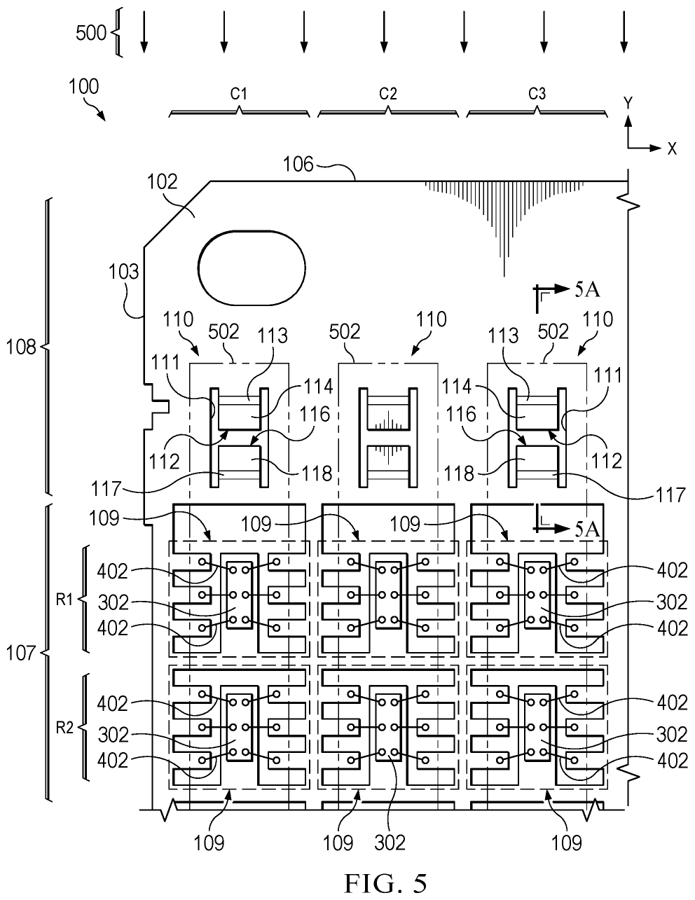

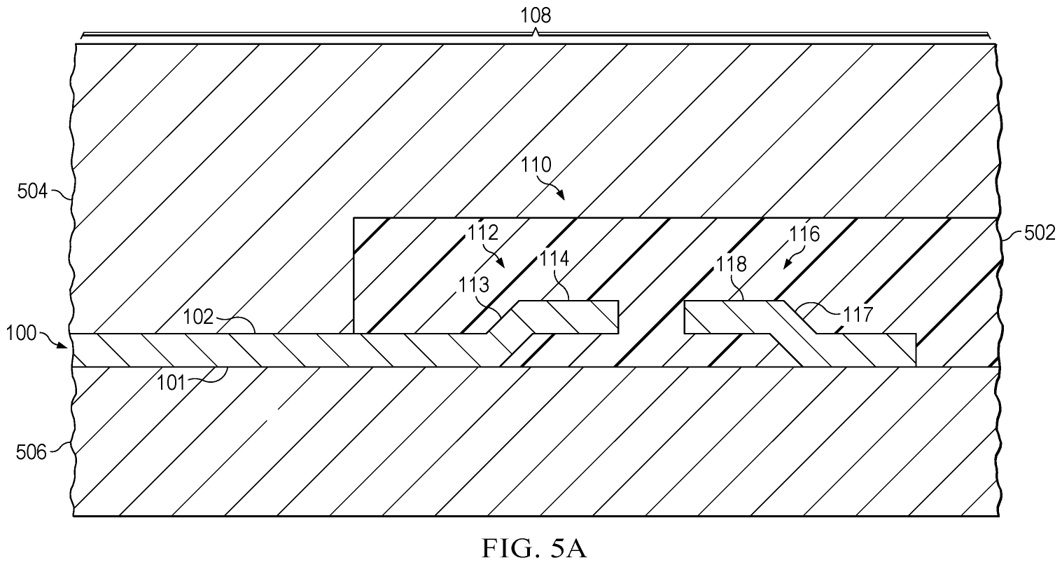

In one implementation, the lead frame 100 is designed for molding operations with a mold (e.g., FIG. 5A below) with column-wise cavities filled from the bottom to the top and the mold locking structures 110 are positioned in the upper side portion 108 near the mold material exhaust or exit port of each column. The positioning of the mold locking structures 110 near the mold exit port facilitates mold structure adherence to the lead frame panel array 100 during and after molding operations in fabrication of electronic devices and thereby helps to mitigate or avoid package cracking and associated effects.

As best shown in FIG. 1A, the example mold locking structures 110 include an opening 111 that extends through the metal structure of the lead frame 100. In the illustrated example, the mold locking structure opening 111 has a capital H-shape. The top sides of the die attach pads and prospective lead conductive features in the interior portion 107 of the lead frame 100 have upper surfaces that define a lead frame plane of the respective first and second directions X and Y (e.g., an X-Y lead frame plane) that is coplanar with the top side 102 of the lead frame 100. The individual mold locking structures 110 include conductive metal features that extend outside the plane of the first and second directions X, Y along the third direction Z as best shown in FIG. 1B.

In the example of FIGS. 1A and 1B, the individual mold locking structures 110 include a raised feature 112 that extends outward from the lead frame plane of the lead frame 100. The first raised feature 112 includes a first portion 113 that extends at a nonzero angle to the plane of the lead frame 100 at least partially upward along the third direction Z and a second portion 114 connected to the first portion 113 and approximately parallel to the lead frame plane. The raised feature 112 allows molding compound to extend in the capital H-shaped opening 111 around the first and second portions 113 and 114 including mold compound that extends under the lower sides of the portions 113 and 114. The extension of a molded package structure under the raised feature 112 opposes forces that may tend to separate the molded package structure from the lead frame 100 during fabrication operations during and after molding.

In the illustrated example, moreover, the mold locking structure 110 includes a second raised feature 116 that is laterally spaced apart along the second direction Y by a distance 115 from the first raised feature 112 and extends outward from the lead frame plane at least partially along the third direction Z. The second raised feature 116 in this example includes a first portion 117 that extends at a nonzero angle to the plane of the lead frame 100 at least partially upward along the third direction Z and a second portion 118 connected to the first portion 117 and approximately parallel to the lead frame plane. The second raised feature 116 allows molding compound to extend in the capital H-shaped opening 111 around the first and second portions 117 and 118 including mold compound that extends under the lower sides of the portions 117 and 118.

Extension of a molded package structure under the raised features 112 and/or 116 opposes forces that may tend to separate the molded package structure from the lead frame 100 during fabrication operations during and after molding. In one implementation, upper and lower mold structures used in the molding process create a molded package structure that extends around upper and lower surfaces of the raised features 112 and 116, for example, as illustrated and described further below in connection with FIGS. 5 and 5A.

As shown in FIG. 1A, the individual unit areas 109 in this example have a respective die attach pad 119 to accommodate mounting of one or more semiconductor dies (not shown) during fabrication of individual packaged electronic devices in the respective unit areas 109. In addition, the individual unit areas 109 in this example have one or more conductive features spaced apart from the associated die attach pad 119, and the conductive features correspond to prospective leads of the finished electronic device. The prospective lead conductive features in this example have upper surfaces that extend in the lead frame plane and the raised features 112 and 116 are spaced apart from the lead frame plane of the respective first and second directions X and Y.

The lead frame 100 can be or include any suitable conductive metal, such as copper, aluminum, alloys thereof, etc. The lead frame 100 can be fabricated using any suitable processing techniques and equipment, including stamping, etching and/or combinations thereof to form the conductive metal structures of the interior portion 107 and the side portions 108. In one example, the lead frame 100 is a copper metal structure having a thickness 121 and the raised features 112 and 116 of the mold locking structure 110 extend outward from the lead frame plane such that the bottom sides of the second portions 114 and 118 are spaced apart from the plane of the bottom or first side 101 by a distance 120 (e.g., an upset distance) as shown in FIG. 1B. In one example, the distance 120 is 0.162 mm+/−0.030 mm. In another implementation, the raised features 112 and 116 of the mold locking structures 110 in the mold air vent in the upper side portion 108 (e.g., and/or the lower side portion 108 near the mold inlet port) can have an upset raised structure of approximately 0.1 mm+/−0.02, for example, to help mold compound filling in top and bottom sides in order to lock the mold to the lead frame 100 at one or both of the side portions 108. In these or another example, the upset height (e.g., the spacing distance 120) and tolerance can be the same dimension as other upset features of the lead frame 100, for example, in order to facilitate low cost lead frame assembly.

In one implementation (e.g., FIGS. 5 and 5A below), a lower mold portion engages the bottom or first side 101 portions of the lead frame 100 during molding and provides a gap under all or portions of the bottom sides of the raised features 112 and 116 such that molding compound extends under all or portions of the raised features 112 and 116 of the mold locking structure 110. The mold locking structure 110 allows a column length molded structure (e.g., referred to as a molded bar) to better adhere to the lead frame 100 during fabrication processing steps and helps to eliminate mold bar peeling off, particularly on the air vent side portion 108 (e.g., the upper side portion 108 in the view of FIG. 1).

The improved mold material/lead frame adherence reduces the thermal and/or mechanical stress applied to the semiconductor dies within unit areas 109 along a given column of the interior portion 107 until the individual packaged electronic devices are separated from the lead frame panel array structure. The upset extension of the raised features 112 and 116 outside the lead frame plane allows mold compound formation at least partially under the raised features 112 and 116 to inhibit movement of the end of the molded structure relative to the lead frame 100, even when used with single-sided molds having a cavity only on the top side of each individual column the bottom mold structure engaging the bottom of the lead frame 100.

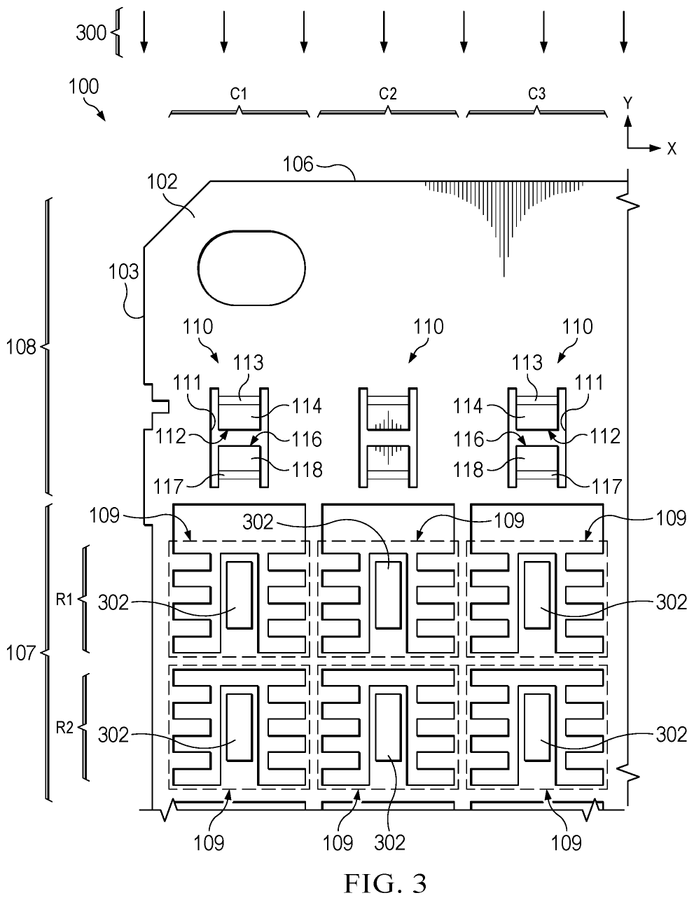

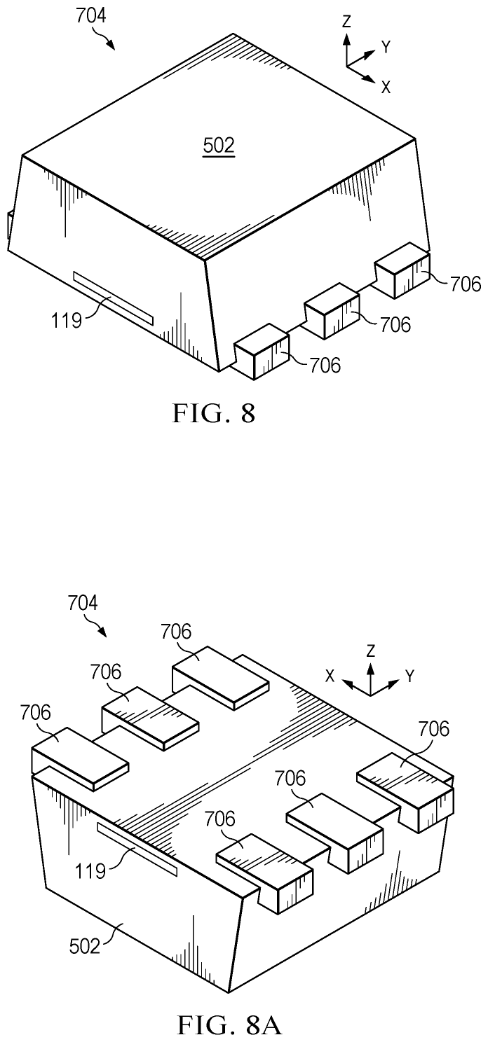

Referring now to FIGS. 2-8A, FIG. 2 shows a method 200 for making an electronic device, FIGS. 3-7 show fabrication of packaged electronic devices using an implementation of the lead frame 100 described above, and FIGS. 8 and 8A show top and bottom perspective views of an example electronic device fabricated according to an example implementation of the method 200.

The method 200 begins with die attach processing at 202 in FIG. 2. FIG. 3 shows a portion of the lead frame 100 in the form of a panel array with conductive metal features (e.g., copper, aluminum, etc.) with unit areas 109 formed in rows and columns as described above. A die attach process 300 is performed in FIG. 3 that mounts a semiconductor die 302 onto the associated die attach pad (e.g., die attach pads 119 in FIG. 1A above) in one or more of the individual unit areas 109 of the lead frame 100. The die attach process 300 can include, for example, dispensing, printing, or otherwise providing solder or conductive or nonconductive adhesive in select portions of top sides of certain lead frame features, as well as placement of semiconductor dies 302 and/or passive components in corresponding locations on the solder paste or adhesive (e.g., using automated pick and place equipment, not shown), and subsequent solder reflow and/or curing processing (e.g., thermal reflow, thermal adhesive curing, UV adhesive curing, etc.) to adhere the semiconductor dies 302 to the corresponding locations of the lead frame panel array 100.

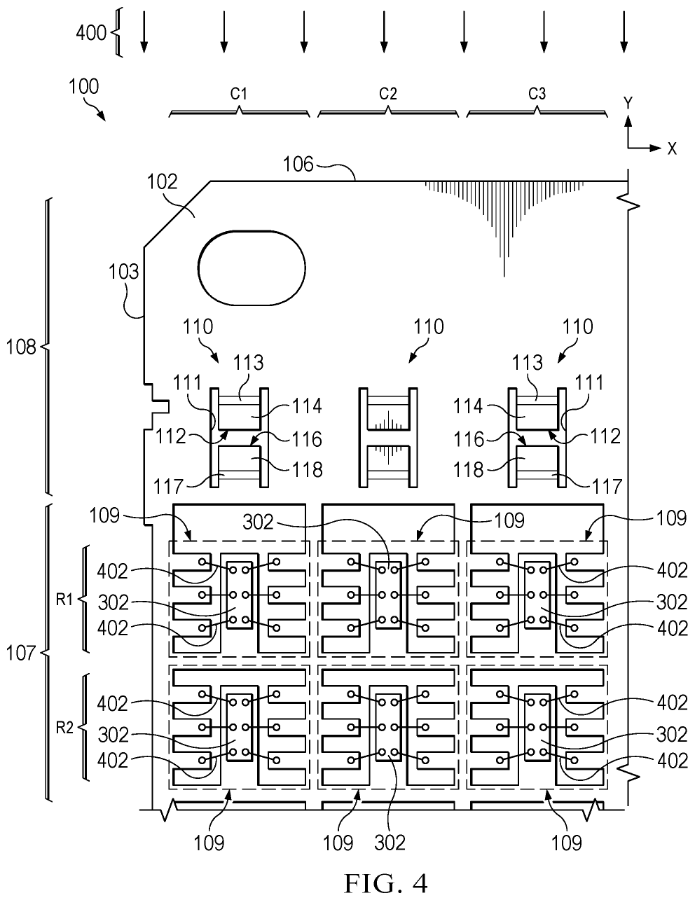

The method 200 continues with wire bonding or other electrical connection processing at 204 in FIG. 2. FIG. 4 shows one example, in which a wire bonding process 400 is performed that creates bond wires 402 for the electrical circuit connections of the semiconductor dies 302 and respective conductive metal features corresponding to prospective leads in each unit area 109 of the lead frame panel array 100. In another implementation, further and/or different bond wires (not shown) and/or soldered metal clips, substrates with routing connections, etc. (not shown) can be created and/or installed at 204, for example, to provide desired electrical circuit connections in each unit area 109. In the illustrated example, the bond wires 402 provide electrical connection of at least one conductive terminal (e.g., a copper or aluminum bond pad) of the respective semiconductor dies 302 to a conductive feature in the corresponding unit area 109 of the lead frame 100.

The method 200 continues at 206 in FIG. 2 with molding processing to form molded package structures along columns of the lead frame panel array 100. FIG. 5 shows one example, in which a molding process 500 is performed using a mold (shown in FIG. 5A) that forms a molded package structure 502 along each of the columns of the lead frame panel array 100. The individual molded package structures 502 extend over the semiconductor die and the bond wires in each unit area 109. The package structure 502 in this example encloses the die attach pad of each unit area 109, although not a requirement of all possible implementations.

As shown in FIG. 5A, one example implementation of the molding process 500 uses a first (e.g., upper) mold portion 504 and a second (e.g., lower) mold portion 506, the first mold portion 504 engages the top side 102 in the illustrated side portion 108 of the lead frame 100 and has a cavity that defines a top and sidewalls of the molded package structure 502. The second mold portion 506 engages the opposite bottom side 101 in the side portion 108 and defines a bottom of the molded package structure 502 in the gap under the raised features 112 and 116 of the mold locking structure 110. In one implementation, the second mold portion 506 provides a gap under all or portions of the bottom sides of the raised features 112 and 116 such that molding compound of the molded package structure 502 extends under all or portions of the raised features 112 and 116 of the mold locking structure 110.

In the example of FIG. 5A, the upper surface of the second mold portion 506 is substantially flat and planar, and also engages bottom sides of the prospective lead conductive metal structures in the unit areas 109 of the interior portion 107 of the lead frame 100. In another example, the upper surface of the second mold portion 506 can include raised features (not shown) that extend above the plane of the bottom surfaces of the prospective lead features in the interior portion 107 of the lead frame 100, for example, to create packaged electronic devices having leads that are slightly below the bottom side of a molded package structure of the finished product. The molded package structure 502 in this example extends around upper and lower surfaces of the raised features 112 and 116, including all or portions of the angled first portions 113 and 117, and the second portions 114 and 118 as shown in FIG. 5A.

The molded package structures 502 in the illustrated example of FIG. 5 extend along respective columns of the panel array from above the mold locking structures 110 of the upper side portion 108, through multiple unit areas 109 of the column in the interior portion 107, and into the lower side portion 108 of the lead frame 100. In addition, as shown in FIG. 5A, the molded package structure 502 extends under the mold locking structure 110 in the side portion 108 of the lead frame 100 at the upper end of the respective columns. In implementations where the lower side portion 108 includes a mold locking structure 110 in one or more of the array columns, the molded package structure 502 extends under those mold locking structures 110.

The raised features 112 and 116 of the mold locking structures 110 are enclosed by the molded package structure 502, and the raised features 112 and 116 are spaced apart from the bottom of the molded package structure 502 along the third direction Z as shown in FIG. 5A. The extension of the molded package structure 502 under the mold locking structures 110 in one or both of the side portions 108 opposes separation of the molded package structure 502 from the side portion 108 of the lead frame 100 during fabrication processing. In one implementation, having mold locking structures 110 in both of the side portions 108, the molding process 500 forms the molded package structure 502 that extends under the first and second mold locking structures 110 at respective first and second ends of one or more columns to oppose separation of the molded package structure 502 from the side portions 108 of the lead frame 100.

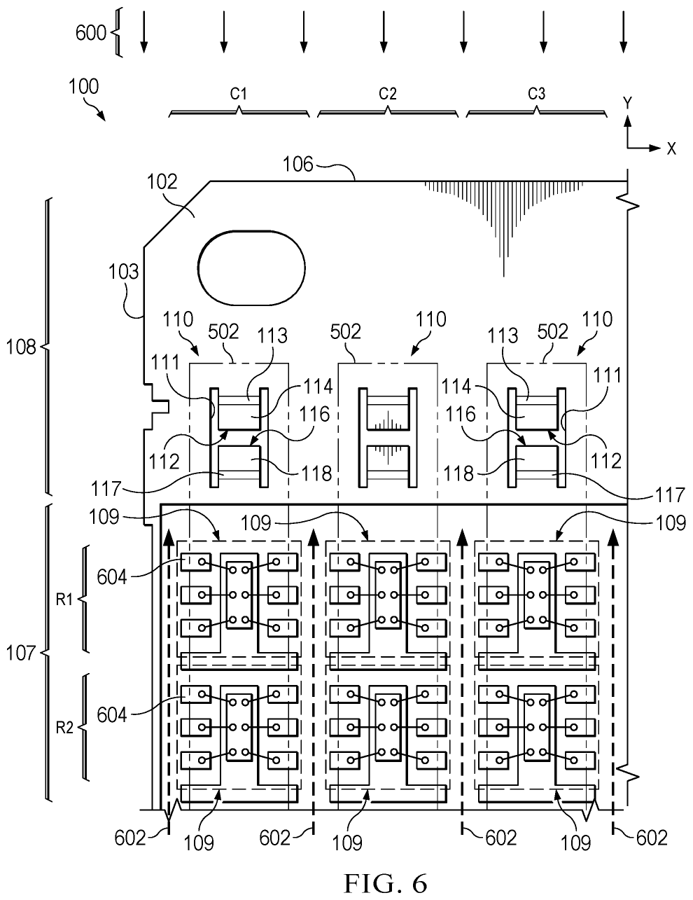

The method 200 continues at 208 in FIG. 2 with column direction package separation, in one example including lead trimming and optional lead forming. FIG. 6 shows one example, in which the separation process 600 is performed along the lines 602 (e.g., along the second direction Y in the illustrated orientation) to separate adjacent columns of unit areas 109 from one another, including trimming leads 604 that originally extended between laterally neighboring unit areas 109. In one example, the separation process 600 is a saw blade cutting operation using one or more cutting blades, such as a single cutting blade performing one cut at a time along the respective lines 602. In another implementation, laser cutting and/or other separation steps can be used alone or in combination with blade cutting to perform single or multiple pass separation along the lines 602. In a further implementation, the separation process 600 can include punching operations and/or other processing to form separated leads along the lateral sides of the unit areas 109 into a desired shape, such as j-leads, gullwing leads, etc. (not shown).

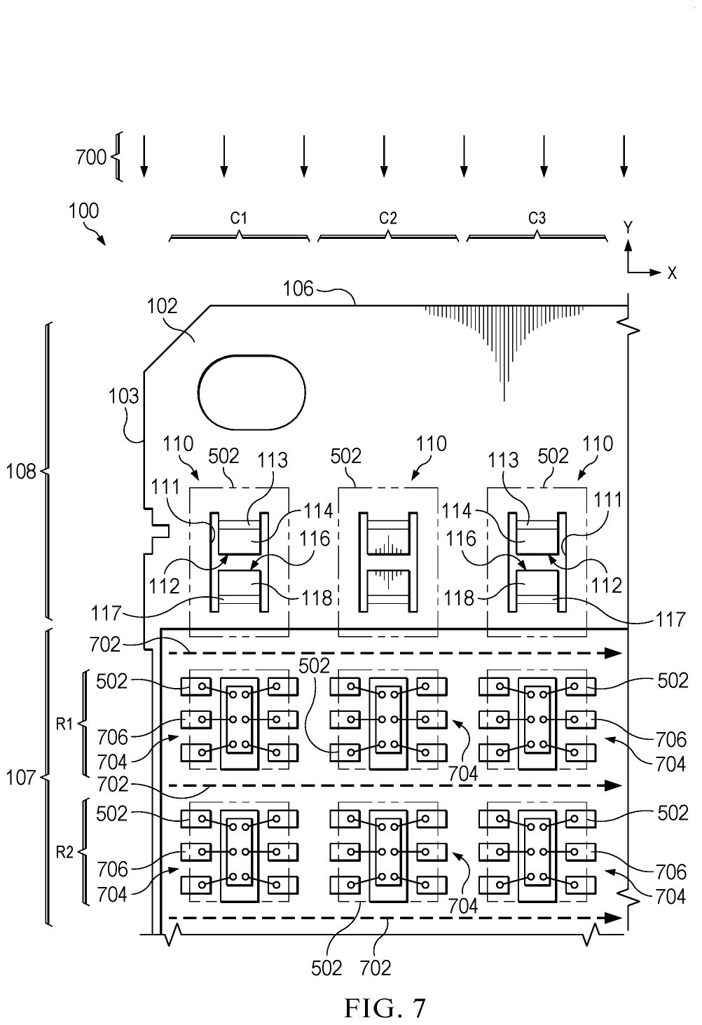

The conductive features that are trimmed at 208 to form individual electronic device leads in one example extend in the lead frame plane, and bottoms of the trimmed leads are exposed outside the molded package structure 502 after the separation processing at 208. In one example, the method can include optional plating operations after lead trimming and forming at 208, for example, to plate the exposed surfaces of the prospective device leads to provide plated leads 706 as illustrated in FIG. 7.

The method 200 continues at 210 in FIG. 2 with row direction package separation to separate individual packaged electronic devices from one another along each column in the array. FIG. 7 shows one example, in which a separation process 700 is performed (e.g., saw blade cutting, laser cutting, chemical etching, combinations thereof, etc.). The separation process 700 separates finished packaged electronic devices 704 and adjacent rows and unit areas of each column from one another along lines 702 and separates the uppermost row R1 from the illustrated side portion 108 and the molded structure 502 that encloses the raised features 112 and 116 of the mold locking structures 110 of each column as shown in FIG. 7.

FIGS. 8 and 8A show an example of a resulting packaged electronic device 704 following separation from and associated column of the original lead frame panel array structure. As shown in FIGS. 8 and 8A, the row direction package separation processing at 210 in one example cuts through the opposite sides of the molded package structure 502 and cuts through a portion of the original starting die attach pad (e.g., 119 in FIG. 1A above) which remains exposed along the side of the molded package structure 502. As further shown in FIGS. 8 and 8A, the illustrated example has trimmed and plated conductive leads 706 exposed outside the lateral sides of the molded package structure 502, including exposed bottom surfaces that are spaced apart from the bottom side of the molded package structure 502 (e.g., FIG. 8A). The package separation processing at 210 separates the electronic devices 704 of the respective unit areas 109 from the lead frame 100, and also separates the upper and lower side portions 108 from the remainder of the respective columns of the original array structure.

In one example, the outer periphery of the starting lead frame 100 can remain a unitary structure (e.g., the cutting operations along the first and/or second directions X and/or Y need not extend all the way through the peripheral edge of the lead frame 100, although not a requirement of all possible implementations. In another implementation, moreover, the column direction separation processing at 208 can include separating conductive leads from tie bars or mold bars with partial cutting of the molded package structure 502 in order to form leads (not shown) that have lateral sides that are flush with the sidewalls of the molded package structure 502.

The lead frame examples 100 and the method 200 provide solutions to facilitate reduction in mold structure separation from the lead frame 100 during fabrication processing as a panel array, and thereby mitigate or avoid package cracking as well as resulting thermal and/or mechanical stress applied to the semiconductor dies within the molded structure during manufacturing.

Modifications are possible in the described examples, and other implementations are possible, within the scope of the claims.

What is claimed is:

1. A method of fabricating an electronic device, the method comprising:
mounting a semiconductor die in a unit area of a lead frame;
electrically connecting the semiconductor die to a conductive feature in the unit area of the lead frame;
performing a molding process to form a molded package structure that extends through multiple unit areas of the lead frame along a first column of the lead frame and extends under a mold locking structure in a side portion of the lead frame at an end of the first column to oppose separation of the molded package structure from the side portion of the lead frame;
separating the first column from an adjacent second column of the lead frame;
separating an electronic device of the unit area from the lead frame; and
separating the side portion from the first column of the lead frame.

2. The method of claim 1, wherein the molding process is performed using first and second mold portions, the first mold portion engages a first side of the lead frame and has a cavity that defines a top and sidewalls of the molded package structure, and the second mold portion engages an opposite second side of the lead frame and defines a bottom of the molded package structure.

3. The method of claim 2, wherein:
the mold locking structure includes a raised feature that extends outward from a plane of the lead frame; and
the molded package structure extends around upper and lower surfaces of the raised feature.

4. The method of claim 3, wherein:
the conductive feature in the unit area of the lead frame is a prospective lead of the electronic device that extends in the plane of the lead frame;
a bottom side of the prospective lead is exposed outside the molded package structure;
the raised feature is enclosed by the molded package structure; and
the raised feature is spaced apart from the bottom of the molded package structure.

5. The method of claim 3, wherein:
the mold locking structure includes a second raised feature that extends outward from the plane of the lead frame; and
the molded package structure extends around upper and lower surfaces of the second raised feature.

6. The method of claim 5, wherein each raised feature includes:
a first portion that extends at an angle to the plane of the lead frame; and
a second portion connected to the first portion and approximately parallel to the plane of the lead frame.

7. The method of claim 3, wherein the raised feature includes:
a first portion that extends at an angle to the plane of the lead frame; and
a second portion connected to the first portion and approximately parallel to the plane of the lead frame.

8. The method of claim 7, wherein the molded package structure extends around upper and lower surfaces of the raised feature.

9. The method of claim 1, wherein the molded package structure extends around upper and lower surfaces of the mold locking structure.

10. The method of claim 1, wherein:
the mold locking structure includes a raised feature that extends outward from a plane of the lead frame; and
the molded package structure extends around upper and lower surfaces of the raised feature.

11. The method of claim 10, wherein:
the mold locking structure includes a second raised feature that extends outward from the plane of the lead frame; and
the molded package structure extends around upper and lower surfaces of the second raised feature.

12. The method of claim 10, wherein each raised feature includes:
a first portion that extends at an angle to the plane of the lead frame; and
a second portion connected to the first portion and approximately parallel to the plane of the lead frame.

13. The method of claim 1, wherein:
the conductive feature in the unit area of the lead frame is a prospective lead of the electronic device; and
separating the first column from the adjacent second column of the lead frame includes trimming the prospective lead.

14. The method of claim 1, wherein electrically connecting the semiconductor die to the conductive feature in the unit area of the lead frame includes performing a wire bonding process (400) that forms a bond wire between the semiconductor die and the conductive feature.

15. The method of claim 1, wherein the molding process forms the molded package structure that extends under a second mold locking structure in a side portion of the lead frame at a second end of the first column to oppose separation of the molded package structure from the side portion of the lead frame.

16. A lead frame, comprising:
an interior portion having unit areas arranged in an array with rows along a first direction and columns along an orthogonal second direction, the respective unit areas having a die attach pad and a conductive feature in a plane of the first and second directions; and
a side portion extending from the interior portion to an edge of the lead frame and including a mold locking structure aligned with a column and spaced apart from the interior portion, the mold locking structure extending outside the plane of the first and second directions.

17. The lead frame of claim 16, wherein the mold locking structure includes a raised feature that extends outward from the plane of the first and second directions.

18. The lead frame of claim 17, wherein:
the conductive feature in the respective unit areas is a prospective lead that extends in the plane of the first and second directions; and
the raised feature is spaced apart from the plane of the first and second directions.

19. The lead frame of claim 17, wherein each raised feature includes:
a first portion that extends at an angle to the plane of the lead frame; and
a second portion connected to the first portion and approximately parallel to the plane of the first and second directions.

20. The lead frame of claim 16, wherein the mold locking structure includes a second raised feature that extends outward from the plane of the first and second directions.
